(19) United States
(12) Patent Application Publication
(10) Pub. No.: US 2024/0297637 A1
(43) Pub. Date: Sep. 5, 2024

(54) Resonator Device

(71) Applicant: SEIKO EPSON CORPORATION, Tokyo (JP)

(72) Inventors: Takashi YAMAZAKI, Shiojiri (JP); Takuro KOBAYASHI, Minowa (JP); Juichiro MATSUZAWA, Minamiminowa (JP)

(21) Appl. No.: 18/592,675

(22) Filed: Mar. 1, 2024

(30) Foreign Application Priority Data
Mar. 2, 2023 (JP) 2023-031671

(51) Int. Cl. H03H 9/215; H03H 9/02; H03H 9/05; H03H 9/10

(52) U.S. Cl. CPC H03H 9/215; H03H 9/02157; H03H 9/0509; H03H 9/105

(57) ABSTRACT

A resonator device includes a resonator element, and a base to which the resonator element is fixed via a conductive adhesive. The resonator element includes a base portion, a vibrating arm that is coupled to the base portion and that extends in a first direction, and a support arm that is arranged with the vibrating arm in a second direction orthogonal to the first direction, that extends in the first direction, and that is fixed to the base by the conductive adhesive. 0.2×L1≤Da≤0.4×L1, in which a position at a base end of the support arm is P0, a central position of the conductive adhesive is Pa, and a length between P0 and Pa is Da in the first direction of the support arm.

The present application is based on, and claims priority from JP Application Serial Number 2023-031671, filed Mar. 2, 2023, the disclosure of which is hereby incorporated by reference herein in its entirety.

### BACKGROUND

### 1. Technical Field

The present disclosure relates to a resonator device.

### 2. Related Art

JP-A-2011-14977 discloses a piezoelectric resonator including a tuning fork type piezoelectric resonator element that includes a base portion and a vibrating arm including a pair of bottomed grooves extending from the base portion and in which a width of the vibrating arm and a width of the grooves are changed in a tapered shape from a base portion side toward a tip end side. By narrowing the width of the vibrating arm and the width of the grooves from the base portion side toward the tip end side, a CI value in a fundamental wave mode is made smaller than a CI value in a second harmonic mode, a CI value ratio that is the CI value in the second harmonic mode/the CI value in the fundamental wave mode is 1 or more, and oscillation in the harmonic mode is prevented.

JP-A-2011-14977 is an example of the related art.

However, in the piezoelectric resonator that is a resonator device in JP-A-2011-14977, when the CI value in the fundamental wave mode is made small, the CI value in the second harmonic mode also decreases, and when further miniaturization is intended, there is a possibility that the CI value ratio cannot be set to 1 or more only with the tapered structure of the vibrating arm and the grooves. That is, when further miniaturization is intended, there is a possibility that the oscillation in the harmonic mode cannot be prevented.

### SUMMARY

A resonator device including a resonator element, and a base to which the resonator element is fixed via a conductive adhesive, in which the resonator element includes a base portion, a vibrating arm that is coupled to the base portion and that extends in a first direction, and a support arm that is arranged in a second direction with the vibrating arm when a direction orthogonal to the first direction is the second direction, that extends in the first direction, and that is fixed to the base by the conductive adhesive, the vibrating arm includes an arm, and a wide portion that is located on an opposite side of the arm from a base portion side and whose length along the second direction is larger than that of the arm, the arm includes a first surface, a second surface, a first side surface, and a second side surface, a first groove is formed on a first surface side and a second groove is formed on the second surface side, a width Wa of the arm satisfies 30 μm≤Wa≤75 μm, a thickness T between the first surface and the second surface of the arm satisfies 110 μm≤T≤150 μm, 0.884≤(t1+t2)/T≤0.990, in which a depth of the first groove is t1 and a depth of the second groove is t2, 0.0056≤Wb/T≤0.0326, in which a width of the first surface arranged across the first groove and a width of the second surface arranged across the second groove are Wb, a length L1 of the vibrating arm satisfies L1≤1000 μm, and 0.2×L1≤Da≤0.4×L1, in which a position at a base end of the support arm is P0, a central position of the conductive adhesive is Pa, and a length between P0 and Pa is Da in the first direction of the support arm.

A resonator device including a resonator element, and a base to which the resonator element is fixed via a conductive adhesive, in which the resonator element includes a base portion, a vibrating arm that is coupled to the base portion and that extends in a first direction, and a support arm that is arranged in a second direction with the vibrating arm when a direction orthogonal to the first direction is the second direction, that extends in the first direction, and that is fixed to the base by the conductive adhesive, the vibrating arm includes an arm, and a wide portion that is located on an opposite side of the arm from a base portion side and whose length along the second direction is larger than that of the arm, the arm includes a first surface, a second surface, a first side surface, and a second side surface, a first groove is formed on a first surface side and a second groove is formed on a second surface side, a width Wa of the arm satisfies 30 μm≤Wa≤75 μm, a thickness T between the first surface and the second surface of the arm satisfies 110 μm≤T≤150 μm, 0.884≤(t1+t2)/T≤0.990, in which a depth of the first groove is t1 and a depth of the second groove is t2, 0.0056≤Wb/T≤0.0326, in which a width of the first surface arranged across the first groove and a width of the second surface arranged across the second groove are Wb, a length L1 of the vibrating arm satisfies L1≤1000 μm, when the vibrating arm vibrates in a second harmonic mode, an antinode located on a most base-end side among a plurality of antinodes and nodes of vibration generated in the support arm is a first antinode, and 0.5×D1≤Da≤1.5×D1, in which a position at a base end of the support arm is P0, a position of the first antinode is P1, a central position of the conductive adhesive is Pa, a length between P0 and P1 is D1, and a length between P0 and Pa is Da in the first direction of the support arm.

### BRIEF DESCRIPTION OF THE DRAWINGS

FIG. 1 is a plan view showing a configuration of a resonator device according to a first embodiment.

FIG. 2 is a cross-sectional view taken along a line A1-A1 in FIG. 1.

FIG. 3 is a plan view showing a configuration of a resonator element according to the embodiment.

FIG. 4 is a cross-sectional view taken along a line A2-A2 in FIG. 3.

FIG. 5 is a diagram showing a relationship between a groove depth and a CI value.

FIG. 6 is a diagram showing a relationship between a width of a first surface and a second surface arranged across grooves and a CI value.

FIG. 7 is a plan view showing a configuration of a resonator device according to a second embodiment.

FIG. 8 is a plan view showing a configuration of a resonator device according to a third embodiment.

FIG. 9 is a plan view showing a configuration of a resonator device according to a fourth embodiment.

### DESCRIPTION OF EMBODIMENTS

### 1. First Embodiment

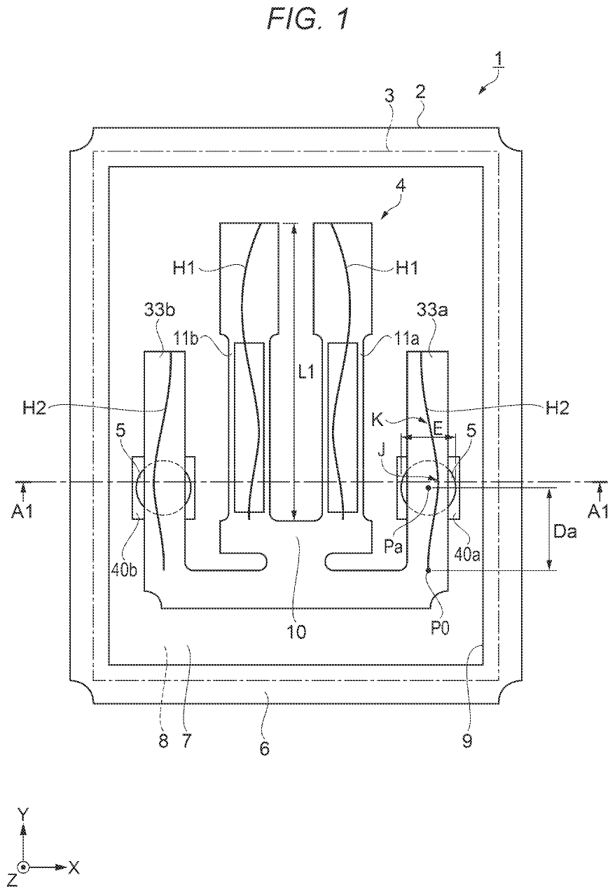

A resonator device 1 according to the embodiment will be described with reference to FIGS. 1 to 6.

For convenience of description, in each of the following FIGS. 1 to 4 and 7 to 9, an X axis, a Y axis, and a Z axis are illustrated as three axes orthogonal to one another. Further, a direction along the X axis is referred to as an “X direction”, a direction along the Y axis is referred to as a “Y direction”, and a direction along the Z axis is referred to as a “Z direction”. Further, an arrow side of each axis is also referred to as a “plus side”, and a side opposite to an arrow is also referred to as a “minus side”. Further, the plus side in the Z direction is also referred to as “upper”, and the minus side in the Z direction is also referred to as “lower”. Further, for convenience of description, in the following FIGS. 1 to 4 and 7 to 9, illustration of an electrode provided at a resonator element 4 is omitted, and in FIGS. 1 and 2 and FIGS. 7 to 9, illustration of wiring provided at an inner bottom surface 7 of a base 2 and an external terminal provided at a lower surface 8 of the base 2 is omitted. Further, in the embodiment, the Y direction is a first direction, and the X direction is a second direction.

### 1.1. Resonator Device

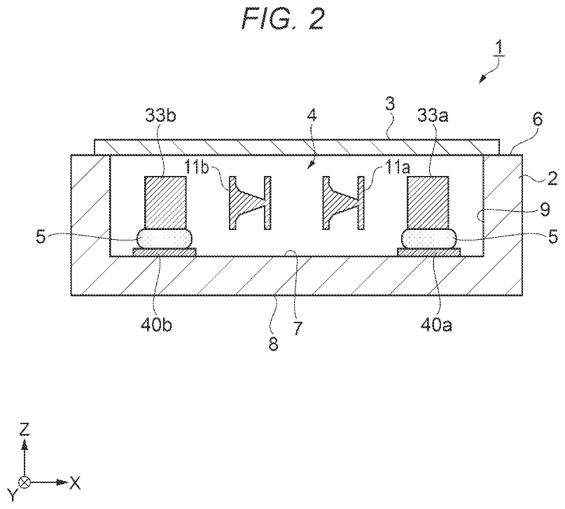

As shown in FIGS. 1 and 2, the resonator device 1 according to the embodiment includes a tuning fork-shaped resonator element 4, the base 2 that houses the resonator element 4, a lid 3 that is joined to the base 2 and hermetically seals a housing space that houses the resonator element 4, and conductive adhesives 5 that fix the resonator element 4 to the base 2.

The base 2 has a recess 9 opened in an upper surface 6, and the resonator element 4 is housed in the recess 9. Internal terminals 40a and 40b that fix the resonator element 4 via the conductive adhesives 5 and that are electrically coupled to an electrode (not shown) provided at the resonator element 4 are disposed at the inner bottom surface 7 of the base 2, and an external terminal (not shown) electrically coupled to the internal terminals 40a and 40b by wiring (not shown) is disposed at a lower surface 8 of the base 2.

The lid 3 has a flat plate shape, and is joined to the upper surface 6 of the base 2 via a joining member such as a solder, low-melting-point glass, or a seam ring such that inside of the recess 9 that houses the resonator element 4 is hermetically sealed.

The resonator element 4 is disposed such that a substantially central portion thereof in the Y direction that is the first direction of support arms 33a and 33b disposed on both sides in the X direction that is the second direction in which a base portion 10 and a pair of vibrating arms 11a and 11b are sandwiched overlaps the internal terminals 40a and 40b, more specifically, such that the support arm 33a overlaps the internal terminal 40a, and the support arm 33b overlaps the internal terminal 40b and is fixed to the inner bottom surface 7 of the base 2 via the conductive adhesives 5.

Therefore, when the electrode provided at the resonator element 4 and the external terminal are electrically coupled to each other and a drive signal is applied to the external terminal, tip ends of the vibrating arms 11a and 11b can be subjected to flexural vibration in the X direction by repeatedly approaching and separating from each other.

The vibrating arms 11a and 11b are designed such that a resonance frequency in a fundamental wave mode is 32.768 kHz. However, the vibrating arms 11a and 11b may vibrate with a plurality of vibration modes. For example, the vibrating arms 11a and 11b may vibrate with the fundamental wave mode of 32.768 kHz and a second harmonic mode around 250 kHz. In such a case, when a CI value ratio, which is a CI value in the second harmonic mode/a CI value in the fundamental wave mode, is smaller than 1, the resonator element 4 may easily oscillate in the second harmonic mode instead of the desired fundamental wave mode. Therefore, it is necessary to make the CI value ratio larger than 1 in order to cause the resonator element 4 to oscillate in the fundamental wave mode of 32.768 kHz. That is, it is necessary to make the CI value in the second harmonic mode larger than the CI value in the fundamental wave mode.

Here, as shown in FIG. 1, vibration in the second harmonic mode is displaced like a shape H1 of the schematically shown vibrating arms 11a and 11b. Further, at the same time, vibration of the vibrating arms 11a and 11b in the second harmonic mode is transmitted to the support arms 33a and 33b via the base portion 10, and the vibrating arms 11a and 11b vibrate like a shape H2 of the schematically shown support arms 33a and 33b. Therefore, the vibration of the vibrating arms 11a and 11b in the second harmonic mode can be prevented, and the CI value in the second harmonic mode can be increased by restraining an antinode J having large displacement at the antinode J and a node K of the vibration generated in the support arms 33a and 33b, that is, by fixing with the conductive adhesives 5 or the like. In the embodiment, the term “node” means a portion where displacement due to the vibration generated in the support arms 33a and 33b is the smallest. Further, in the embodiment, the term “antinode” means a portion where displacement due to the vibration generated in the support arms 33a and 33b is the largest between two adjacent nodes.

In the resonator device 1 according to the embodiment, a diameter E of the conductive adhesive 5 is 120 μm or more, and when a length Da between a position P0 at a base end of the support arm 33a or 33b and a central position Pa of the conductive adhesive 5 in the Y direction of the support arms 33a and 33b uses a length L1 of the vibrating arms 11a and 11b as a reference, 0.2×L1≤Da≤0.4×L1 is satisfied. With such a range, a vicinity of the antinode J of the vibration generated in the support arms 33a and 33b can be restrained, and the CI value in the second harmonic mode can be increased.

When the length Da between the position P0 at the base end of the support arm 33a or 33b and the central position Pa of the conductive adhesive 5 uses the length L1 of the vibrating arms 11a and 11b as a reference, it is more preferable that 0.25×L1≤Da≤0.35×L1 is satisfied. With such a range, the vicinity of the antinode J of the vibration generated in the support arms 33a and 33b can be further restrained, and the CI value in the second harmonic mode can be further increased.

### 1.2. Resonator Element

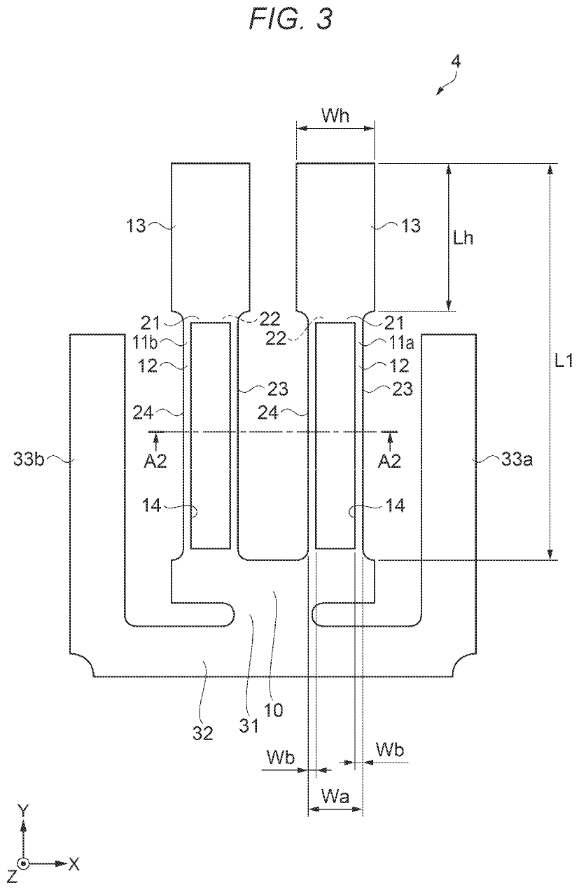

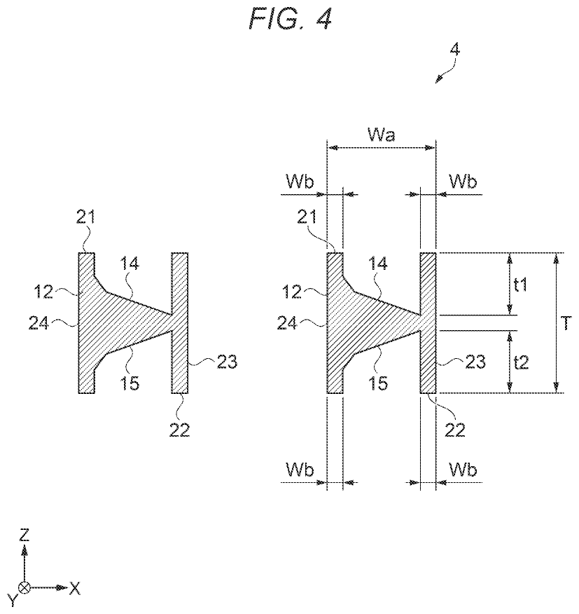

As shown in FIGS. 3 and 4, the resonator element 4 provided in the resonator device 1 according to the embodiment has the tuning fork shape including the pair of support arms 33a and 33b that sandwich the base portion 10 and the pair of vibrating arms 11a and 11b and that are coupled to the base portion 10.

The resonator element 4 is formed by patterning a Z-cut quartz crystal substrate into a desired shape, has a spread in an X-Y plane defined by the X axis and the Y axis that are crystal axes of quartz crystal, and has a thickness along the Z direction.

The resonator element 4 includes the base portion 10, the pair of vibrating arms 11a and 11b that extend from the base portion 10 to the plus side in the Y direction and that are arranged in the X direction, and the pair of support arms 33a and 33b that is coupled to the minus side in the Y direction of the base portion 10, that extend to the plus side in the Y direction, and that are arranged in the X direction. The vibrating arm 11a and the support arm 33a are located on the plus side in the X direction, and the vibrating arm 11b and the support arm 33b are located on the minus side in the X direction.

The vibrating arms 11a and 11b each include an arm 12, and a wide portion 13 that is located on an opposite side of the arm 12 from a base portion 10 side. In the wide portion 13, a width that is a length in the X direction is larger than that of the arm 12.

The arm 12 includes a first surface 21, a second surface 22, a first side surface 23, and a second side surface 24, and is formed with a bottomed first groove 14 opened in the first surface 21 on a first surface 21 side and a bottomed second groove 15 opened in the second surface 22 on a second surface 22 side.

The first groove 14 and the second groove 15 extend in the Y direction. Further, as shown in FIG. 4, cross sections of the first groove 14 and the second groove 15 have a shape in which a crystal plane of the quartz crystal appears. This is because the resonator element 4 is formed by wet etching. Since an etching rate in the minus X direction is lower than an etching rate in the plus X direction due to etching anisotropy of the quartz crystal, a side surface in the minus X direction has a relatively gentle inclination, and a side surface in the plus X direction has a nearly perpendicular inclination.

The support arms 33a and 33b are coupled to tip end portions of a support portion 32, which extends from a coupling portion 31 coupled to the minus side in the Y direction of the base portion 10 to the plus side in the X direction and the minus side in the X direction, and extend to the plus side in the Y direction. The support arm 33a is coupled to the tip end portion of the support portion 32 on the plus side in the X direction, and the support arm 33b is coupled to the tip end portion of the support portion 32 on the minus side in the X direction. Therefore, by fixing the substantially central portions of the support arms 33a and 33b in the Y direction, as compared with a case where the related-art base portion 10 is fixed by the conductive adhesives 5, a distance from the vibrating arms 11a and 11b to the fixing portions can be sufficiently increased, and an influence of vibration leakage from the vibrating arms 11a and 11b and distortion from the conductive adhesives 5 can be reduced.

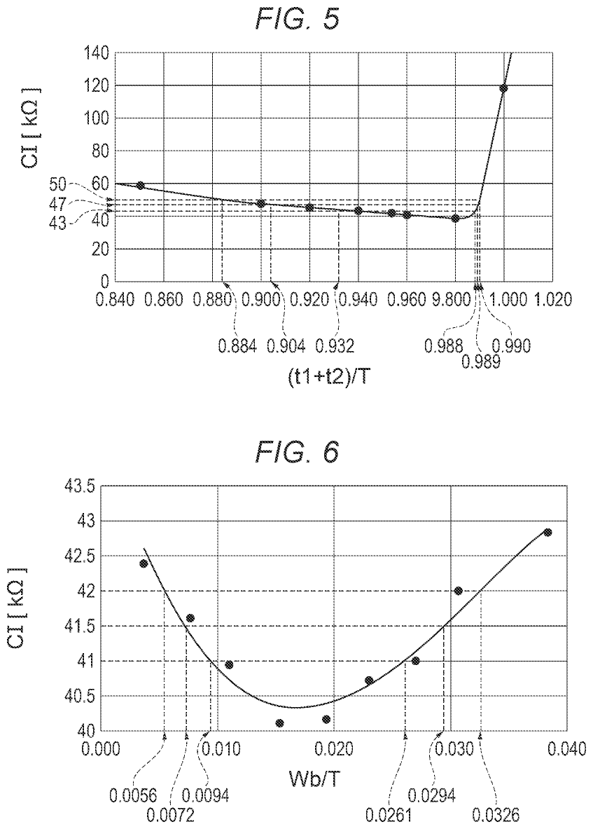

Next, optimum values of dimensions for reducing the CI value of the resonator element 4 will be described with reference to FIGS. 5 and 6.

FIGS. 5 and 6 show simulation results. In the following description, a simulation using the resonator element 4 formed by patterning the Z-cut quartz crystal substrate and having a flexural vibration frequency (mechanical flexural vibration frequency) f=32.768 kHz will be representatively used. However, discoverers have confirmed that in the range of the flexural vibration frequency f of 32.768 kHz±1 kHz, there is almost no difference from simulation results shown below.

In the present simulation, the resonator element 4 obtained by patterning the quartz crystal substrate by wet etching is used. Therefore, as described above, the cross sections of the first groove 14 and the second groove 15 have the shape in which the crystal plane of the quartz crystal appears as in FIG. 4.

The vibrating arms 11a and 11b of the resonator element 4 used in the present simulation each have the length L1 of 993 μm, a thickness T of 130 μm, and a width Wa of 70 μm. The discoverers have confirmed that there is almost no difference from simulation results shown below when the length L1 is within a range of 500 μm to 1000 μm with L1≤1000 μm, the thickness T is within a range of 110 μm to 150 μm, and the width Wa is within a range of 30 μm to 75 μm. Further, the resonator element 4 in which no electrode is formed is used in the present simulation.

FIG. 5 shows simulation results indicating a relationship between the CI value and (t1+t2)/T obtained by adding a maximum depth t1 of the first groove 14 and a maximum depth t2 of the second groove 15 and standardizing an added result by the thickness T. From FIG. 5, when 0.884≤(t1+t2)/T≤0.990 is satisfied, the CI value of the resonator element 4 can be reduced to 50 kΩ or less. This is considered to be because when (t1+t2)/T is 0.884 or more, a facing area between side-surface electrodes provided at the first side surface 23 and the second side surface 24 of the arm 12 and groove electrodes provided in the first groove 14 and the second groove 15 is sufficiently secured, an electric field efficiency of a portion sandwiched by the side-surface electrode and the groove electrode is improved, and the CI value is reduced. Further, it is considered that when (t1+t2)/T is 0.990 or less, a portion sandwiched by the first groove 14 and the second groove 15 remains to some extent, rigidity of the vibrating arms 11a and 11b is secured, unnecessary vibration such as oblique vibration can be reduced, vibration efficiency of the flexural vibration that is main vibration is improved, and the CI value is reduced.

When 0.904≤(t1+t2)/T≤0.989 is satisfied, the CI value of the resonator element 4 can be reduced to 47 kΩ or less. Further, when 0.932≤(t1+t2)/T≤0.988 is satisfied, the CI value of the resonator element 4 can be further reduced to 43 kΩ or less.

FIG. 6 shows simulation results indicating a relationship between the CI value and Wb/T obtained by standardizing, by the thickness T, a width Wb of the first surfaces 21 arranged across the first groove 14 and the width Wb of the second surfaces 22 arranged across the second groove 15. From FIG. 6, when 0.0056≤Wb/T≤0.0326 is satisfied, the CI value of the resonator element 4 can be reduced to 42 kΩ or less. It is considered that when Wb/T is 0.0056 or more, the rigidity of the vibrating arms 11a and 11b is secured, the unnecessary vibration such as oblique vibration can be reduced, the vibration efficiency of the flexural vibration that is the main vibration is improved, and the CI value is reduced. Further, it is considered that when Wb/T is 0.0326 or less, an interval between the side-surface electrode and the groove electrode is secured to some extent, the electric field efficiency of the portion sandwiched by the side-surface electrode and the groove electrode is improved, and the CI value is reduced.

When 0.0072≤Wb/T≤0.0294 is satisfied, the CI value of the resonator element 4 can be further reduced to 41.5 kΩ or less. Further, when 0.0094≤Wb/T≤0.0261 is satisfied, the CI value of the resonator element 4 can be further reduced to 41 kΩ or less.

When the thickness T between the first surface 21 and the second surface 22 of the arm 12 is smaller than 110 μm, the depth t1 of the first groove 14 and the depth t2 of the second groove 15 become small, and the facing area between the side-surface electrode and the groove electrode cannot be sufficiently secured. Therefore, it is difficult to reduce the CI value. Further, when the thickness T is larger than 150 μm, it is necessary to increase the width Wa of the arm 12 in order to satisfy 0.884≤(t1+t2)/T≤0.990, and it becomes difficult to miniaturize the resonator element 4. The thickness T preferably satisfies 120 μm≤T≤140 μm. Further, the thickness T more preferably satisfies 125 μm≤T≤135 μm.

A width Wh of the wide portion 13 preferably satisfies 130 μm≤Wh≤190 μm. When the width Wh is smaller than 130 μm, mass effect cannot be sufficiently exhibited. When the width Wh is larger than 190 μm, an interval between the two wide portions 13 becomes narrow, and the vibrating arms 11a and 11b are likely to break when the wide portions 13 come into contact with each other. Therefore, when the width Wh satisfies 130 μm≤Wh≤190 μm, the mass effect can be sufficiently exhibited, and the miniaturization can be achieved.

A length Lh of the wide portion 13 preferably satisfies 200 μm≤Lh≤400 μm. When the length Lh is smaller than 200 μm, the mass effect cannot be sufficiently exhibited. When the length Lh is larger than 400 μm, the length L1 of the vibrating arms 11a and 11b increases, and the miniaturization becomes difficult. Therefore, when the length Lh satisfies 200 μm≤Lh≤400 μm, the mass effect can be sufficiently exhibited, and the miniaturization can be achieved.

As described above, in the resonator device 1 according to the embodiment, the length Da between the position P0 at the base end of the support arm 33a or 33b and the central position Pa of the conductive adhesive 5 in the Y direction of the support arms 33a and 33b satisfies 0.2×L1≤Da≤0.4×L1 with reference to the length L1 of the vibrating arms 11a and 11b. Therefore, the vicinity of the antinode J of the vibration generated in the support arms 33a and 33b can be restrained, and the CI value in the second harmonic mode can be increased. Therefore, oscillation in the harmonic mode can be prevented.

Further, a relationship between the depths t1 and t2 of the first groove 14 and the second groove 15 and the thickness T satisfies 0.884≤(t1+t2)/T≤0.990. Furthermore, a relationship between the width Wb of the first surface 21 and the second surface 22 and the thickness T satisfies 0.0056≤Wb/T≤0.0326. Therefore, the electric field efficiency of the portion sandwiched by the side-surface electrode and the groove electrode is improved, the rigidity of the vibrating arms 11a and 11b is secured, the unnecessary vibration such as oblique vibration can be reduced, the vibration efficiency of the flexural vibration that is the main vibration is improved, and the CI value can be reduced. Therefore, the small-sized resonator device 1 having a small CI value can be obtained.

### 2. Second Embodiment

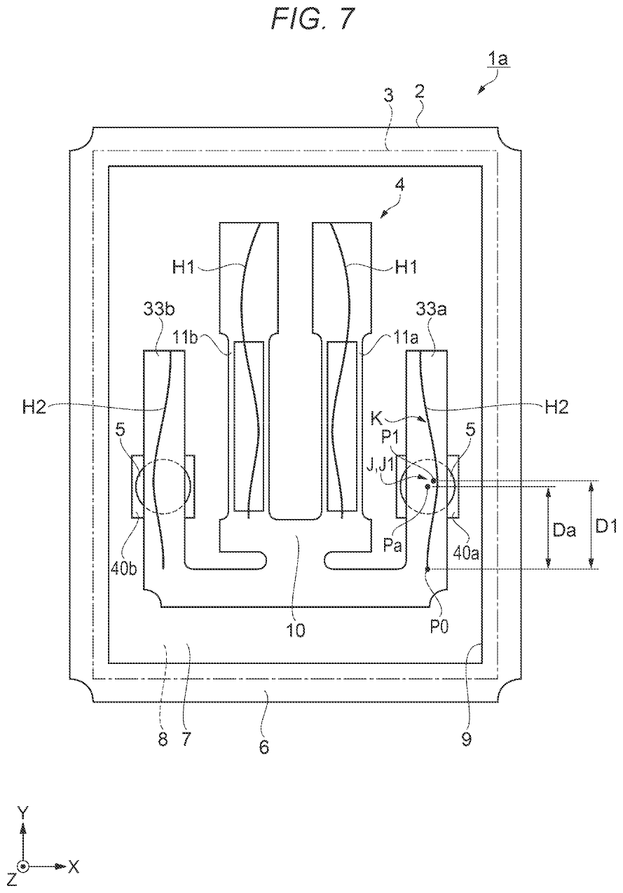

Next, a resonator device 1a according to a second embodiment will be described with reference to FIG. 7.

As compared with the resonator device 1 according to the first embodiment, the resonator device 1a according to the embodiment is the same as the resonator device 1 according to the first embodiment except that a definition method for indicating a range of the length Da between the position P0 at the base end of the support arm 33a or 33b and the central position Pa of the conductive adhesive 5 is different. Differences from the first embodiment described above will be mainly described, similar matters will be denoted by the same reference signs, and description thereof will be omitted.

As shown in FIG. 7, the resonator device 1a includes the base 2, the lid 3, the resonator element 4, and the conductive adhesives 5. The base 2 and the lid 3 constitute a package that houses the resonator element 4.

In the resonator device 1a, the diameter E of the conductive adhesive 5 is 120 μm or more. Further, when the vibrating arms 11a and 11b vibrate in a second harmonic mode, an antinode J located on a most base-end side among a plurality of antinodes J and nodes K of vibration generated in the support arms 33a and 33b is a first antinode J1, and the length Da between the position P0 at the base end of the support arm 33a or 33b and the central position Pa of the conductive adhesive 5 in the Y direction of the support arms 33a and 33b satisfies 0.5×D1≤Da≤1.5×D1 with reference to a length D1 between the position P0 at the base end of the support arm 33a or 33b and a position P1 of the first antinode J1. With such a range, a vicinity of the first antinode J1 of the vibration generated in the support arms 33a and 33b can be restrained, and a CI value in the second harmonic mode can be increased.

The length Da between the position P0 at the base end of the support arm 33a or 33b and the central position Pa of the conductive adhesive 5 more preferably satisfies 0.75×D1≤Da≤1.25×D1 with reference to the length D1 between the position P0 at the base end of the support arm 33a or 33b and the position P1 of the first antinode J1. With such a range, the vicinity of the antinode J of the vibration generated in the support arms 33a and 33b can be further restrained, and the CI value in the second harmonic mode can be further increased.

As described above, in the resonator device 1a according to the embodiment, the length Da between the position P0 at the base end of the support arm 33a or 33b and the central position Pa of the conductive adhesive 5 in the Y direction of the support arms 33a and 33b satisfies 0.5×D1≤Da≤1.5×D1 with reference to the length D1 between the position P0 at the base end of the support arm 33a or 33b and the position P1 of the first antinode J1. With such a range, when the vibrating arms 11a and 11b vibrate in the second harmonic mode, the vicinity of the first antinode J1 of the vibration generated in the support arms 33a and 33b can be restrained, and the CI value in the second harmonic mode can be increased. Therefore, oscillation in the harmonic mode can be prevented.

Further, a relationship between the depths t1 and t2 of the first groove 14 and the second groove 15 and the thickness T satisfies 0.884≤(t1+t2)/T≤0.990. Furthermore, a relationship between the width Wb of the first surface 21 and the second surface 22 and the thickness T satisfies 0.0056≤Wb/T≤0.0326. Therefore, the electric field efficiency of the portion sandwiched by the side-surface electrode and the groove electrode is improved, the rigidity of the vibrating arms 11a and 11b is secured, the unnecessary vibration such as oblique vibration can be reduced, the vibration efficiency of the flexural vibration that is the main vibration is improved, and the CI value can be reduced. Therefore, the small-sized resonator device 1a having a small CI value can be obtained.

### 3. Third Embodiment

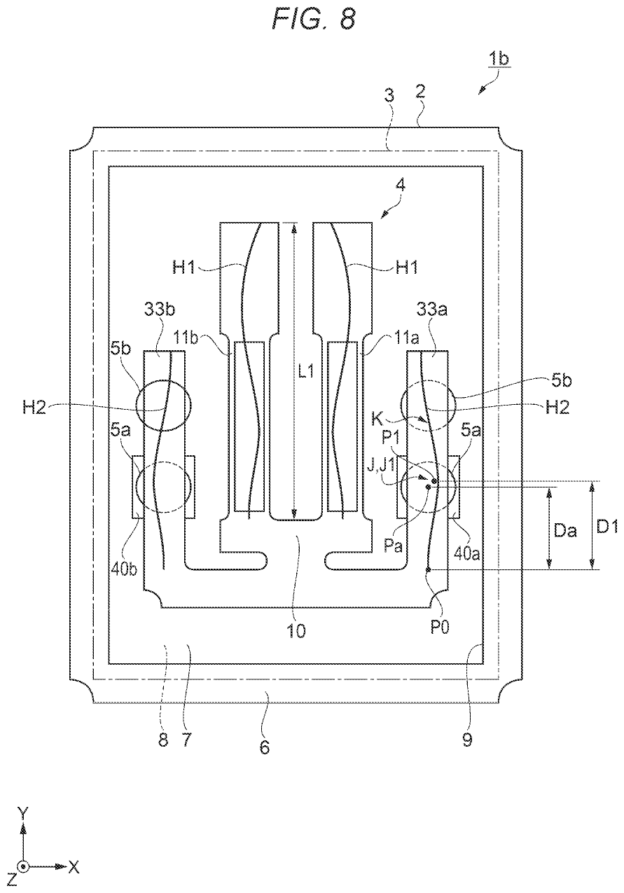

Next, a resonator device 1b according to a third embodiment will be described with reference to FIG. 8.

As compared with the resonator device 1 according to the first embodiment, the resonator device 1b according to the embodiment is the same as the resonator device 1 according to the first embodiment except that the number of conductive adhesives 5a and 5b that fix the support arms 33a and 33b is different. Differences from the first embodiment described above will be mainly described, similar matters will be denoted by the same reference signs, and description thereof will be omitted.

As shown in FIG. 8, the resonator device 1b includes the base 2, the lid 3, the resonator element 4, and the conductive adhesives 5a and 5b. The base 2 and the lid 3 constitute a package that houses the resonator element 4.

In the resonator device 1b, the pair of support arms 33a and 33b are fixed by the two conductive adhesives 5a and 5b arranged in the Y direction. One conductive adhesive 5a between the two conductive adhesives 5a and 5b is disposed on base end sides of the support arms 33a and 33b, and the other conductive adhesive 5b is disposed on a tip end side with respect to the first antinode J1.

The length Da between the position P0 at the base end of the support arm 33a or 33b and the central position Pa of the conductive adhesive 5a satisfies 0.2×L1≤Da≤0.4×L1 with reference to the length L1 of the vibrating arms 11a and 11b, or satisfies 0.5×D1≤Da≤1.5×D1 with reference to the length D1 between the position P0 at the base end of the support arm 33a or 33b and the position P1 of the first antinode J1.

With such a configuration, in the resonator device 1b, when the vibrating arms 11a and 11b vibrate in a second harmonic mode, since two points including the vicinity of the first antinode J1 and the tip end side with respect to the first antinode J1 of the vibration generated in the support arms 33a and 33b are fixed, the vibration generated in the support arms 33a and 33b can be further restrained, and a CI value in the second harmonic mode can be further increased. Therefore, oscillation in the harmonic mode can be prevented.

### 4. Fourth Embodiment

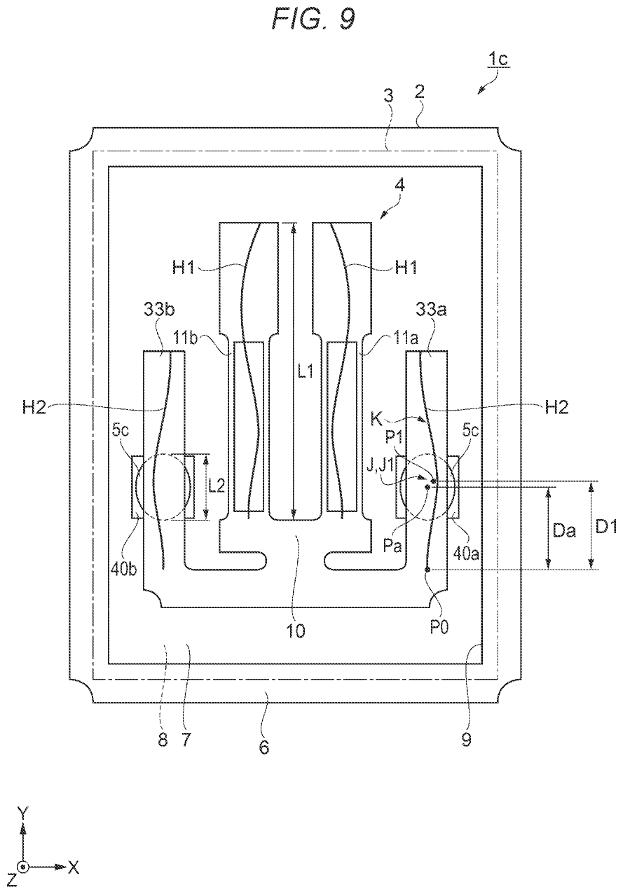

Next, a resonator device 1c according to a fourth embodiment will be described with reference to FIG. 9.

As compared with the resonator device 1 according to the first embodiment, the resonator device 1c according to the embodiment is the same as the resonator device 1 according to the first embodiment except that a shape of conductive adhesives 5c that fix the support arms 33a and 33b is different. Differences from the first embodiment described above will be mainly described, similar matters will be denoted by the same reference signs, and description thereof will be omitted.

As shown in FIG. 9, the resonator device 1c includes the base 2, the lid 3, the resonator element 4, and the conductive adhesives 5c. The base 2 and the lid 3 constitute a package that houses the resonator element 4.

In the resonator device 1c, the conductive adhesives 5c that fix the support arms 33a and 33b have an elliptical shape, and a length L2 in the Y direction that is a longitudinal direction is 150 μm or more. The length Da between the position P0 at a base end of the support arm 33a or 33b and the central position Pa of the conductive adhesive 5c satisfies 0.2×L1≤Da≤0.4×L1 with reference to the length L1 of the vibrating arms 11a and 11b, or satisfies 0.5×D1≤Da≤1.5×D1 with reference to the length D1 between the position P0 at the base end of the support arm 33a or 33b and the position P1 of the first antinode J1. With such a range, a vicinity of the first antinode J1 of vibration generated in the support arms 33a and 33b can be further widely restrained, and a CI value in a second harmonic mode can be further increased.

With such a configuration, in the resonator device 1c, since the length L2 of the conductive adhesives 5c that fix the support arms 33a and 33b in the Y direction is large, when the vibrating arms 11a and 11b vibrate in the second harmonic mode, the vicinity of the antinode J or the first antinode J1 of the vibration generated in the support arms 33a and 33b can be widely fixed, and the CI value in the second harmonic mode can be further increased. Therefore, oscillation in the harmonic mode can be further prevented.

What is claimed is:

1. A resonator device including a resonator element, and a base to which the resonator element is fixed via a conductive adhesive, wherein
the resonator element includes
a base portion,
a vibrating arm that is coupled to the base portion and that extends in a first direction, and
a support arm that is arranged in a second direction with the vibrating arm when a direction orthogonal to the first direction is the second direction, that extends in the first direction, and that is fixed to the base by the conductive adhesive,
the vibrating arm includes an arm, and a wide portion that is located on an opposite side of the arm from a base portion side and whose length along the second direction is larger than that of the arm,
the arm includes a first surface, a second surface, a first side surface, and a second side surface,
a first groove is formed on a first surface side and a second groove is formed on a second surface side,
a width Wa of the arm satisfies 30 μm≤Wa≤75 μm,
a thickness T between the first surface and the second surface of the arm satisfies 110 μm≤T≤150 μm,
0.884≤(t1+t2)/T≤0.990, wherein a depth of the first groove is t1 and a depth of the second groove is t2,
0.0056≤Wb/T≤0.0326, wherein a width of the first surface arranged across the first groove and a width of the second surface arranged across the second groove are Wb,
a length L1 of the vibrating arm satisfies L1≤1000 μm, and
0.2×L1≤Da≤0.4×L1, wherein a position at a base end of the support arm is P0, a central position of the conductive adhesive is Pa, and a length between P0 and Pa is Da in the first direction of the support arm.

2. A resonator device including a resonator element, and a base to which the resonator element is fixed via a conductive adhesive, wherein
the resonator element includes
a base portion,
a vibrating arm that is coupled to the base portion and that extends in a first direction, and
a support arm that is arranged in a second direction with the vibrating arm when a direction orthogonal to the first direction is the second direction, that extends in the first direction, and that is fixed to the base by the conductive adhesive,
the vibrating arm includes an arm, and a wide portion that is located on an opposite side of the arm from a base portion side and whose length along the second direction is larger than that of the arm,
the arm includes a first surface, a second surface, a first side surface, and a second side surface,
a first groove is formed on a first surface side and a second groove is formed on a second surface side,
a width Wa of the arm satisfies 30 μm≤Wa≤75 μm,
a thickness T between the first surface and the second surface of the arm satisfies 110 μm≤T≤150 μm,
0.884≤(t1+t2)/T≤0.990, wherein a depth of the first groove is t1 and a depth of the second groove is t2,
0.0056≤Wb/T≤0.0326, wherein a width of the first surface arranged across the first groove and a width of the second surface arranged across the second groove are Wb,
a length L1 of the vibrating arm satisfies L1≤1000 μm,
when the vibrating arm vibrates in a second harmonic mode, an antinode located on a most base-end side among a plurality of antinodes and nodes of vibration generated in the support arm is a first antinode, and
0.5×D1≤Da≤1.5×D1, wherein a position at a base end of the support arm is P0, a position of the first antinode is P1, a central position of the conductive adhesive is Pa, a length between P0 and P1 is D1, and a length between P0 and Pa is Da in the first direction of the support arm.

3. The resonator device according to claim 1, wherein
when the vibrating arm vibrates in a second harmonic mode, an antinode located on a most base-end side among a plurality of antinodes and nodes of vibration generated in the support arm is a first antinode, and
the support fixed by the two conductive adhesives, one of the conductive adhesives satisfies the 0.2×L1≤Da≤0.4×L1, and the other of the conductive adhesives is fixed to a tip end side with respect to the first antinode.

4. The resonator device according to claim 2, wherein
the support arm is fixed by the two conductive adhesives, one of the conductive adhesives satisfies the 0.5×D1≤Da≤1.5×D1, and the other of the conductive adhesives is fixed to a tip end side with respect to the first antinode.

5. The resonator device according to claim 1, wherein
a diameter of the conductive adhesive is 120 μm or more.

6. The resonator device according to claim 2, wherein
a diameter of the conductive adhesive is 120 μm or more.

7. The resonator device according to claim 1, wherein
a length of the conductive adhesive along the first direction is 150 μm or more.

8. The resonator device according to claim 2, wherein
a length of the conductive adhesive along the first direction is 150 μm or more.

9. The resonator device according to claim 1, wherein
$$0.25 \times L 1 \leq Da \leq 0.35 \times L 1$$

10. The resonator device according to claim 2, wherein
$$0.7 5 \times D 1 \leq Da \leq 1.25 \times D 1.$$

11. The resonator device according to claim 1, wherein
$$0.9 4 \leq ( t 1 + t2 ) / T \leq 0.989 .$$

12. The resonator device according to claim 1, wherein
$$0. 932 \leq ( t 1 + t2 ) / T \leq 0.988 .$$

13. The resonator device according to claim 1, wherein
$$0.0072 \leq W b / T \leq 0.0294 .$$

14. The resonator device according to claim 11, wherein
$$0.0072 \leq W b / T \leq 0.0294 .$$

15. The resonator device according to claim 1, wherein
$$0.0094 \leq W b / T \leq 0.0261 .$$

16. The resonator device according to claim 1, wherein
the thickness T satisfies 120 μm≤T≤140 μm.

17. The resonator device according to claim 11, wherein
the thickness T satisfies 120 μm≤T≤140 μm.

18. The resonator device according to claim 1, wherein
the thickness T satisfies 125 μm≤T≤135 μm.

19. The resonator device according to claim 1, wherein
a width Wh of the wide portion satisfies 130 μm≤Wh≤190 μm.

20. The resonator device according to claim 1, wherein
a length Lh of the wide portion satisfies 290 μm≤Lh≤400 μm.
